(19) United States
(12) Patent Application Publication
(10) Pub. No.: US 2010/0193930 A1
(43) Pub. Date: Aug. 5, 2010

(54) MULTI-CHIP SEMICONDUCTOR DEVICES HAVING CONDUCTIVE VIAS AND METHODS OF FORMING THE SAME

(75) Inventor: Young-Min Lee, Asan-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 12/696,942

(22) Filed: Jan. 29, 2010

(30) Foreign Application Priority Data
Feb. 2, 2009 (KR) 10-2009-0007982

(51) Int. Cl. H01L 25/065; H01L 23/538; H01L 23/52

(52) U.S. Cl. 257/686; 257/693; 257/E23.173; 257/E23.175; 257/E23.141; 257/E25.013

(57) ABSTRACT

A multi-chip device can have a plurality of chips in a stair-step arrangement having respective chip pads thereon. A mold packaging material encapsulates the plurality of chips and at least one conductive via, that is in the mold packaging material and extends from an outer surface of the material, contacts a respective one of the chip pads. A conductive material is in the at least one conductive via.

### CROSS REFERENCE TO RELATED APPLICATION

This U.S. non-provisional patent application claims priority under 35 U.S.C. §119 of Korean Patent Application No. 2009-0007982, filed on Feb. 2, 2009, the entire contents of which are hereby incorporated by reference.

### FIELD OF THE INVENTION

The present invention relates to the field of electronics in general and, more particularly, to semiconductors and methods of forming semiconductors.

### BACKGROUND

Multi-chip packages are known to comprise multiple chips stacked on one another. The chips can be connected to one another and to a printed circuit board comprised in the multi-chip package by wire bonding. For example, it is known to connect a circuit (located on the printed circuit board) to each of the chips comprised in the multi-chip package using a wire. In particular, the circuit may be wired to each of the chip using separate wires. It is also known to connect the printed circuit board in the multi-chip package to each of the chips using what is commonly referred to as daisy-chained wiring whereby each of the chips is wired to other immediately adjacent chips. For example, the circuit can be connected to a first one of the chips by a wire, which is then connected to a second chip, resting on the first chip, by another wire. This type of wiring arrangement can be repeated for each of the chips in the multi-chip package.

One of the problems associated with the use of wires discussed above, is that the wires can consume additional space within the multi-chip package. For example, a portion of the wires connected to the printed circuit board can be formed so that the multi-chip package needs to be wider to accommodate the placement of the wires. Further, the placement of the wires near the top of the multi-chip package may require that the package allow for additional room between the upper most chip and the top of the package.

### SUMMARY

Embodiments according to the invention can provide multi-chip semiconductor devices having conductive vias and methods of forming the same. Pursuant to these embodiments, a multi-chip device can comprise a plurality of chips in a stair-step arrangement including respective chip pads thereon. A mold packaging material encapsulates the plurality of chips and at least one mold packaging material via, that is in the mold packaging material and extends from an outer surface of the material, contacts a respective one of the chip pads. A conductive material is in the at least one mold packaging material via.

Still further embodiments according to the invention can provide methods of forming a multi-chip device comprising forming a plurality of chips in a stair-step arrangement includinghaving respective chip pads thereon, forming a mold packaging material encapsulating the plurality of chips, forming at least one mold packaging material via, in the mold packaging material extending from an outer surface of the material to contact a respective one of the chip pads, and forming a conductive material in the at least one mold packaging material via.

Accordingly, embodiments according to the invention can provide multi-chip packages comprising a plurality of chips in a stair-step arrangement so that edges of the chips are offset from one another. The offset allows the pads (on the chips) to be sufficiently exposed to allow respective vias (filled with conductive material) to contact the pads. The vias extend through a mold packaging material to contact pads and, for example, a signal redistribution layer which can in turn be coupled to a plurality of solder balls located on the multi-chip package. It will be understood that the vias that extend through the mold packaging material may replace conventional wires so that the height and width of the multi-chip package can be reduced. In other words, use of the vias extending through the mold packaging material from the chip pads to the signal redistribution layer can reduce the spacing allowance that would otherwise be needed to provide space for wires to provide the same interconnect.

### BRIEF DESCRIPTION OF THE DRAWINGS

FIGS. 1 and 2 are cross-sectional views illustrating multi-chip packages comprising a plurality of chips therein in a stair-step arrangement utilizing vias that extend through a mold packaging material in some embodiments according to the invention.

FIG. 3 is a perspective view of a multi-chip package comprising a plurality of chips in a stair-step arrangement as illustrated in FIGS. 1 and 2, in some embodiments according to the invention.

FIGS. 4 and 5 are cross-sectional views illustrating multi-chip packages comprising a plurality of chips in a stair-step arrangement utilizing at least one via that extends through the mold packaging material and a plurality of wires in some embodiments according to the invention.

FIG. 6 is a cross-sectional view of two multi-chip packages stacked on one another, each comprising a plurality of chips arranged in a stair-step arrangement in each included vias that extend through the mold packaging material in some embodiments according to the invention.

FIG. 7 is a cross-sectional view which illustrates two multi-chip packages each comprising a plurality of chips in an inverted stair-step arrangement in some embodiments according to the invention.

FIG. 8 is a cross-sectional view that illustrates a multi-chip package comprising two stair-step arrangements of respective chips arranged in mirrored stair-step arrangements in some embodiments according to the invention.

FIG. 9 is a cross-sectional view which illustrates two multi-chip packages comprising chips in a stair-step arrangement where one of the stair-step arrangements is inverted and the other is non-inverted so that the active areas of the chips in each of the stair-step arrangements face one another in some embodiments according to the invention.

FIG. 10 is a perspective view of a multi-chip package included chips arranged in a stair-step arrangement where each of the chips is offset in two directions relative to the other chips in the arrangement in some embodiments according to the invention.

FIG. 11 is a perspective view illustrating multi-chip packages in a stair-step arrangement wherein each of the chips is the same shape and size and each of the chip pads is offset from other chip pads by a rotation in some embodiments according to the invention.

FIG. 12 is a perspective view illustrating multi-chip packages in a stair-step arrangement where each of the chips in the arrangement is the same shape and size and has chip pads located along two edges thereof which are rotated relative to locations of other chip pads in some embodiments according to the invention.

FIG. 13 is a cross-sectional view which illustrates a multi-chip package comprising a plurality of chips arranged an opposing stair-step arrangement that defines a mesa profile in some embodiments according to the invention.

FIG. 14-16 are cross-sectional views which illustrate multi-chip packages comprising a plurality of chips therein connected to vias that extend through the mold packaging material wherein the vias have different sizes, shapes and profiles in some embodiments according to the invention.

FIGS. 17-21 are cross-sectional views which illustrate methods of forming multi-chip packages comprising a plurality of chips in a stair-step arrangement in some embodiments according to the invention.

FIGS. 22-26 are cross-sectional views which illustrate methods of forming multi-chip packages comprising a plurality of chips in a stair-step arrangement in some embodiments according to the invention.

### DETAILED DESCRIPTION OF EMBODIMENTS ACCORDING TO THE INVENTION

While the invention is susceptible to various modifications and alternative forms, specific embodiments thereof are shown by way of example in the drawings and will herein be described in detail. It should be understood, however, that there is no intent to limit the invention to the particular forms disclosed, but on the contrary, the invention is to cover all modifications, equivalents, and alternatives falling within the spirit and scope of the invention as defined by the claims.

The present invention now will be described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element such as a layer, region or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “lateral” or “vertical” may be used herein to describe a relationship of one element, layer or region to another element, layer or region as illustrated in the figures. It will be understood that these terms are intended to encompass different orientations of the device in addition to the orientation depicted in the figures. It will be understood that, although the terms first, second, etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present invention.

Unless otherwise defined, all terms (including technical and scientific terms) used herein have the same meaning as commonly understood by one of ordinary skill in the art to which this invention belongs. It will be further understood that terms used herein should be interpreted as having a meaning that is consistent with their meaning in the context of this specification and the relevant art and will not be interpreted in an idealized or overly formal sense unless expressly so defined herein.

Embodiments of the invention are described herein with reference to cross-section illustrations that are schematic illustrations of idealized embodiments (and intermediate structures) of the invention. The thickness of layers and regions in the drawings may be exaggerated for clarity. Additionally, variations from the shapes of the illustrations as a result, for example, of manufacturing techniques and/or tolerances, are to be expected. Thus, embodiments of the invention should not be construed as limited to the particular shapes of regions illustrated herein but are to include deviations in shapes that result, for example, from manufacturing.

As described herein in greater detail, embodiments according to the invention can provide multi-chip packages comprising a plurality of chips in a stair-step arrangement so that edges of the chips are offset from one another. The offset allows the pads (on the chips) to be sufficiently exposed to allow respective vias (filled with conductive material) to contact the pads. The vias extend through a mold packaging material to contact pads and, for example, a signal redistribution layer which can in turn be coupled to a plurality of solder balls located on the multi-chip package. It will be understood that the vias that extend through the mold packaging material may replace conventional wires so that the height and width of the multi-chip package can be reduced. In other words, use of the vias extending through the mold packaging material from the chip pads to the signal redistribution layer can reduce the spacing allowance that would otherwise be needed to provide space for wires to provide the same interconnect.

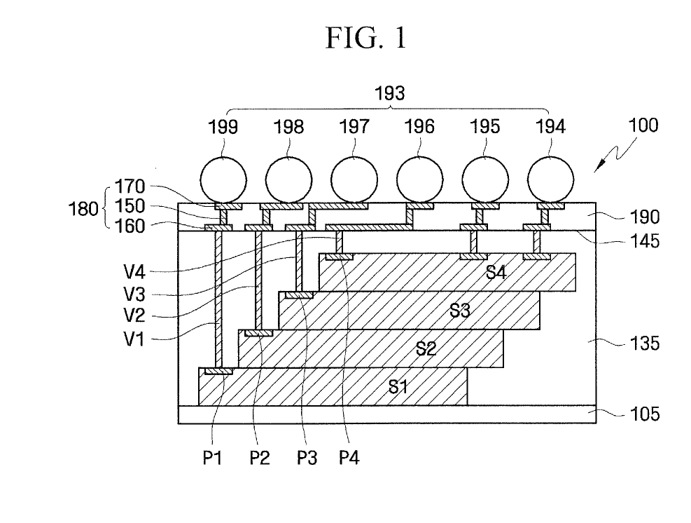

FIG. 1 is a cross-sectional view which illustrates a multi-chip package 100 comprising a plurality of chips S1-S4 in a stair-step arrangement. The stair-step arrangement can provide that the edges of the chips S1-S4 are offset from one another so that respective chip pads P1-P4 located on the chips S1-S4 are sufficiently exposed to allow for contact by vias V1-V4, which are filled with a conductive material.

The vias V1-V4 extend through a mold packaging material 135 from an upper surface thereof to each of the respective chip pads P1-P4. Furthermore, the vias V1-V4 extend through the mold packaging material 135 to contact a signal line 180. It will be understood that the signal line 180 can be employed to distribute signals from the vias V1-V4 within the signal redistribution layer for connection to a plurality of solder balls 194-199 (referred to collectively herein as solder balls 193).

As further shown in FIG. 1, additional vias can be employed to conduct signals from, for example, the upper most chip S4 to the signal line 180 and, further, to the solder balls 193. The chips S1-S4 in the stair-step arrangement can be provided on a supporting layer 105 which can be a silicon, glass, epoxy or circuit board material. The mold packaging material 135 can be an epoxy molding compound or other appropriate material used for insulation of the chips S1-S4, the vias V1-V4 as well as the signal line 180. Still further, the signal line 180 can be conductive line for signal redistribution formed on an outer surface 145 of the mold packaging material 135 or circuit pattern formed in a substrate 190 which can be silicon, glass, or printed circuit board as shown in FIG. 1.

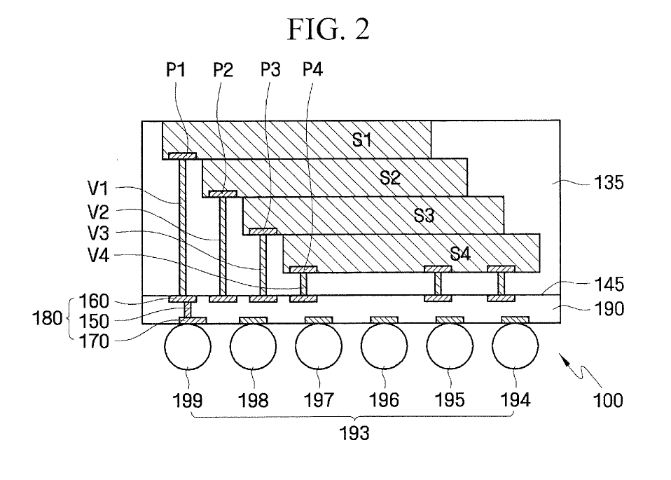

It will be understood that the solder balls 193 can be used to provide connectivity to external circuitry on which the multi-chip package is mounted. For example, the multi-chip package 100 may be mounted on a board by inverting the multi-chip package 100 so that the solder balls 193 are available for mounting on an underlying printed circuit board as shown for example in FIG. 2. In such embodiments, it will be understood that the supporting layer 105 shown in FIG. 1 can be removed when used as shown in FIG. 2.

As shown in FIGS. 1 and 2, it will be understood that the mold packaging material 135 can be used to encapsulate the plurality of chips S1-S4 so that the surface of the upper or lowermost (depending on the orientation) may be covered. For example, as shown in FIG. 1, the mold packaging material 135 encapsulates all of the chips S1-S4, and in particular, S4 so that via V1 extends through at least a portion of the mold packaging material 135 to reach the outer surface 145 of the mold packaging material 135. According to an example shown in FIG. 1, the signal line 180 may have via contacts160 and solder ball lands 170 which can be formed in same level or different level. If the via contacts 160 and solder ball lands are formed in different level, they may be connected by substrate via 150.

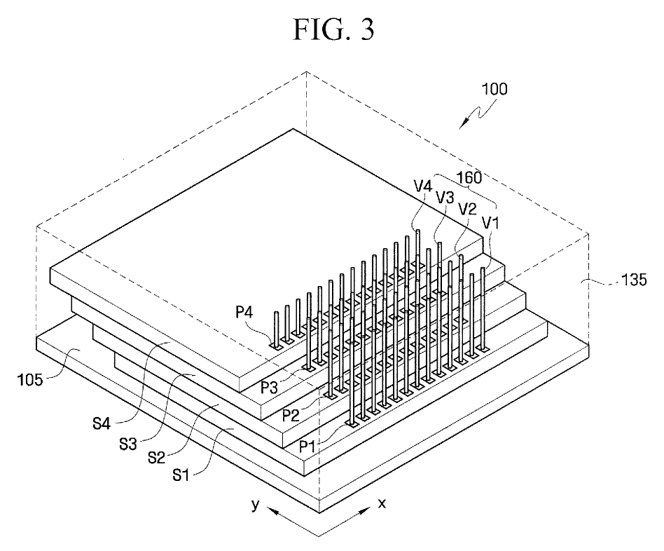

FIG. 3 is a perspective view of the multi-chip package 100 comprising the plurality of chips S1-S4 each offset in the Y direction relative to chips in the stair-step arrangement. As further shown in FIG. 3, the chip pads P1-P4 on each of the chips S1-S4 are located along a single edge of the respective chip S1-S4 on which the pads are located. For example, the pads in the group associated with pad P1 are all located along the single edge of chip S1 extending in the X direction. Likewise, the group of pads in the group associated with pad P2 on chip S2 extend in the X direction along the single edge thereof. The pads of the remaining chips S3 and S4 are similarly situated relative to the pads of chips S1 and S2. As further shown in FIG. 3, the vias contacting each of the pads and extending therefrom upward through the mold packaging material 135 are also offset from one another the same relationship described above in reference to the pads P1-P4.

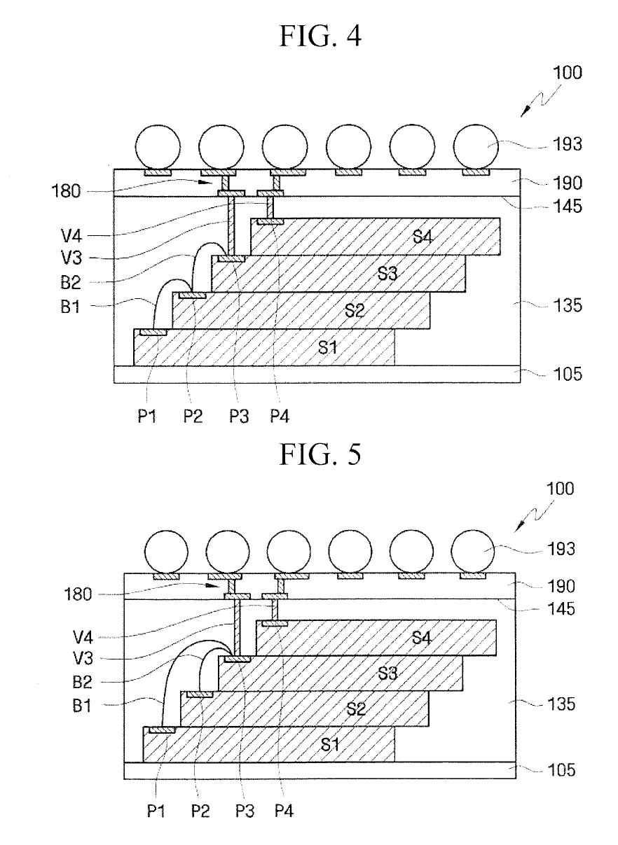

FIG. 4 is a cross-sectional view of the multi-chip package 100 illustrating the plurality of chips S1-S4 in a stair-step arrangement having respective chip pads P1-P4 in some embodiments according to the invention. According to FIG. 4, a single mold packaging via V3 and V4 extend from the pad P3 and P4 on the uppermost chip S4 respectively through the mold packaging material 135 to contact the signal line 180. Electrical conductivity is provided to the remaining chip pads P1-P2 via bonding wires B1 and B2 in a daisy-chain arrangement so that each of the pads is connected in serial to each of the others. Accordingly, in some embodiments according to the invention, the mold packaging material vias extending through the mold packaging material 135 can be combined with wiring utilized in some conventional packages to provide at least some of the advantages provided by embodiments according to the present invention. For example, the embodiments illustrated by FIG. 4 may provide the at least some of the benefit of reducing the height of the multi-chip package 100 by using the via V3 and V4 (rather than a wire) to connect to the signal line 180.

FIG. 5 is a cross-sectional view of the multi-chip package 100 having a plurality of chips S1-S4 in a stair-step arrangement having chip pads P1-P4 formed thereon in some embodiments according to the invention. Further, the mold packaging material via V3 and V4 extends from the chip pad P3 and P4 to contact the signal line 180 respectively, in a similar fashion to the shown in FIG. 4. However, the remaining chip pads P1-P2 are provided electrical conductivity using bonding wires B4 and B5, where each of the wires is connected from the chip pad P3 to each of the other chip pads P1 and P2. Accordingly, the embodiments illustrated by FIG. 5 may provide the at least some of the benefit of reducing the height of the multi-chip package 100 by using the via V3 and V4 (rather than a wire) to connect to the signal line 180.

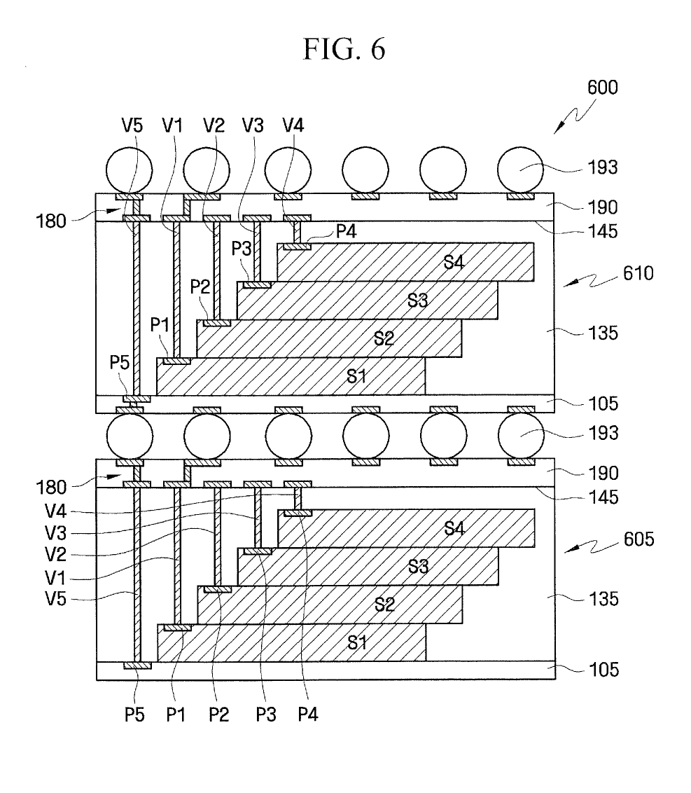

FIG. 6 is a cross-sectional view of two multi-chip packages 605 and 610 in a stacked arrangement 600, where each of the multi-chip packages 605 and 610 is analogous to that described above in reference to FIGS. 1-3 in some embodiments according to the invention. However, in addition to the stair-step arrangement of the plurality of chips S1-S4 in each of the multi-chip packages 605 and 610 and the chip pads therein, each of the multi-chip packages 605 and 610 has chip pads P5 wherein conductivity is provided from the supporting layer 105 directly to the respective signal line 180, without routing through any of the chips S1-S4. In addition, the supporting layer 105 can be signal line or has conductive lines for transporting signals. Accordingly, signals provided to the supporting layer 105 can be provided directly to the signal line 180 of multi-chip package 605 and then further (via the solder balls located between the two multi-chip packages 605 and 610) to the upper multi-chip package 610 which may in turn also be distributed directly to the signal line 180 located within the multi-chip package 610.

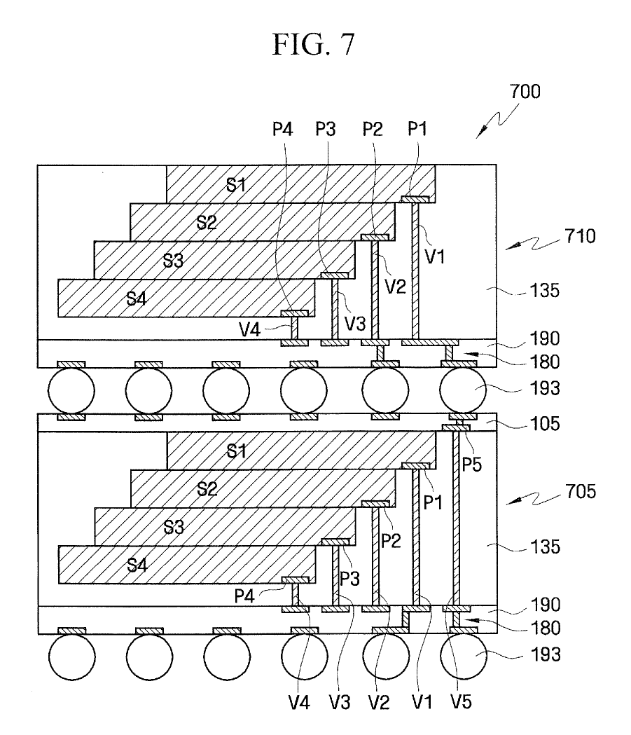

FIG. 7 is a cross-sectional view which illustrates two multi-chip packages 705 and 710 in a stacked arrangement 700 and connected to one another in a similar fashion to that shown in FIG. 6 in some embodiments according to the invention. However, according to FIG. 7, the via V5 connecting the signal line 180 within the multi-chip package 705 is not existed in the multi-chip package 710. Accordingly, in some embodiments according to the invention, different arrangements having the chips arranged in a stair-step arrangement can be mixed and matched with one another to provide the multi-chip package 700. Further, as shown in FIG. 7, the multi-chip packages 705 and 710 can be inverted so with the solder balls of the lower most multi-chip package 705 can be mounted on, for example, a printed circuit board.

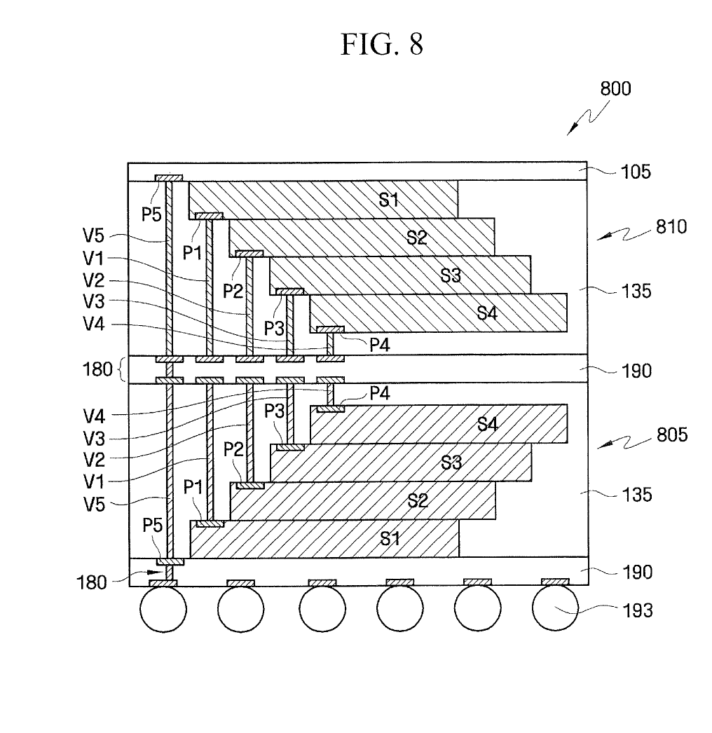

FIG. 8 is a cross-sectional view of a multi-chip package 800 having multi-chip packages 805 and 810 in a stacked arrangement where each of the multi-chip packages 805 and 810 includes a plurality of chips S1-S4 in a stair-step arrangement in some embodiments according to the invention. Further, the chip pads P1-P5 in each of the respective multi-chip packages 805 and 810 face one another as the stair-step arrangement shown in the upper multi-chip package 810 is a mirror image of that provided in the lower multi-chip package 805. According to FIG. 8, the chips S1-S4 comprised in the multi-chip package 805 are in a non-inverted stair-step arrangement, whereas the chips S1-S4 in the multi-chip package 810 are in an inverted stair-step arrangement relative to the chips S1-S4 in multi-chip package 805 so that the stair-step arrangements of chips are a minor image of one another. Furthermore, the multi-chip package 805 and 810 may be directly connected to one another by a signal line 180 therebetween and may avoid, for example, the inclusion of separate(additional?) solder balls (between the multi-chip package 805 and 810) as illustrated in FIGS. 6 and 7. In this example, the via V5 and supporting layer 105 of the multi-chip package 810 can be removed in the multi-chip package 810.

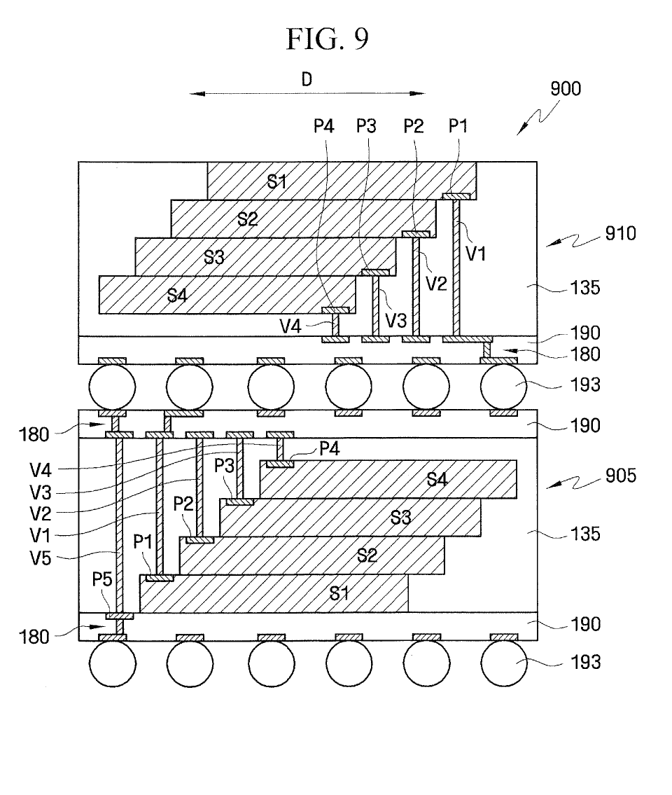

FIG. 9 is a cross-sectional view illustrating a multi-chip device 900 in a stacked arrangement having two multi-chip packages 905 and 910 in some embodiments according to the invention. The multi-chip packages 905 and 910 each have a plurality of chips S1-S4 and respective chips pads P1-P4 located thereon in a stair-step arrangement in some embodiments according to the invention. In addition, FIG. 9 illustrates that the multi-chip package 905 has a fifth chip pad P5 which directly connects the signal line 180 in the multi-chip package 905 to a second signal line 180 and the solder balls 193 as well as the signal line 180 in the multi-chip device 910. As further shown in FIG. 9, the stair-step arrangements of chips S1-S4 are in the multi device as 905 and 910 are arranged so that the chip pads P1-P5 thereon face one another. Further, the chip pads P1-P5 and the vias which extend therefrom V1-V5 in the multi-chip device 905 are offset from the pads and chips in the multi-chip device 910, in the direction D. In this example, the solder balls 193 and at least one signal line 180 disposed between the multi-chip packages 905 and 910 can be removed as shown in FIG. 8.

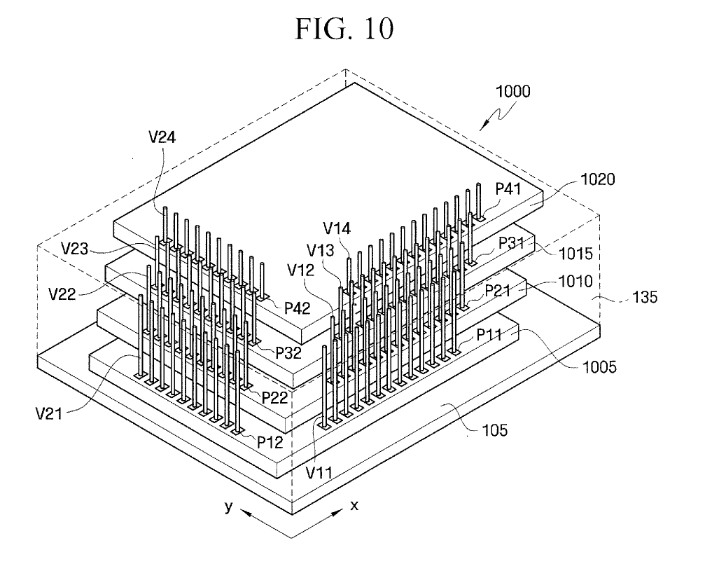

FIG. 10 is a perspective view of a multi-chip device 1000 having a plurality of chips S1-S4, each being the same size and shape in a stair-step arrangement so that the chips are offset from one another in both the X and Y directions in some embodiments according to the invention. Further, chip pads are located along immediately adjacent edges of each of the chips S1-S4, so that respective chip pads are sufficiently exposed to allow for contact by vias. Similarly, the chip pads and vias on each of the chips are offset from the chip pads and vias located along the same edges of the other chips in the stair-step arrangement.

For example, via 22 shown along a first edge of the stair-step arrangement is offset from the via V21 in both the X and Y direction. Similarly, via V23 is offset from each of the vias and V21 and V22 in the X and Y direction. Further, the via V24 is also offset in the X and Y direction from each of the previously described vias V21, V22, and V23. The same holds true for each of the other vias located along the first edge of the arrangement. Still further shown in FIG. 10, the via V12 located along the second edge of the arrangement, which is immediately adjacent to the first edge, is offset in both the X and Y direction relative to the V11. Similarly, the via V13 is also offset in both the X and Y directions relative via V11 and via V12. Still further, via V14 is also offset in the X and Y direction from each of the previously described vias located along the second edge of the arrangement. Moreover, each of the chip pads P12, P22, P32, and P42 are similarly offset from one another in both the X and Y direction in a fashion analogous to that described above with reference to the vias located along the first edge. Still further, the chip pads P11, P21, P31, and P41 are also offset from one another in both the X and Y direction.

FIG. 11 is a perspective view of a multi-chip device 1100 having a plurality of chips S1-S4 in a stair-step arrangement in some embodiments according to the invention. As further shown in FIG. 11, each of the plurality of chips S1-S4 may be substantially same shape and size and the pads located thereon are located along a single edge of each of the chips. For example, according to FIG. 11, a row of chip pad P11 and vias V11 are located along an edge of the chip S1 whereas a similar row of chip pads P22-P44 and vias V22-V44 are located along a first edge of each chips S2-S4. As further illustrated in FIG. 11, each of the edges, along which the respective chip pads and vias for each of the chips S1-S4 are located, is rotated relative to the other chips in the stair-step arrangement. For example, according to FIG. 11, the chips pads P33 and vias V33 on the chip S3 are rotated in the direction R by 90 degrees relative to the chip pads P22 and vias V22 located on the chip S2. Similarly, the chip pads P44 and vias V44 on the chip S4 are rotated relative to the chip S3 rotated by 90 degrees. Still further, the chip pads P11 and vias V11 located on the chip S1 are rotated relative to the chip pads and vias on S4 and those on S2 by a rotation of 90 degrees.

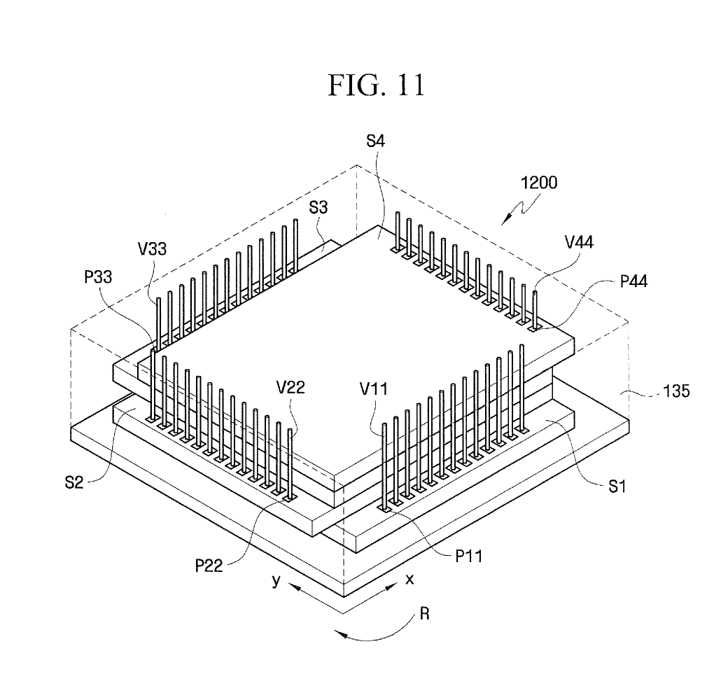

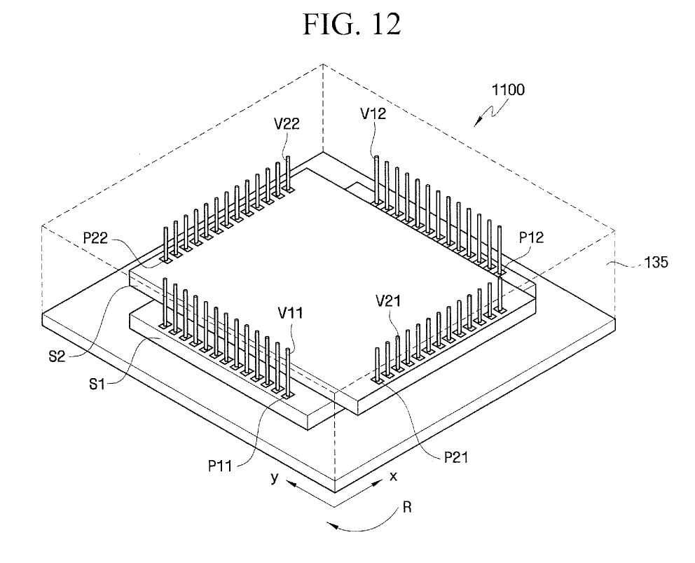

FIG. 12 is a perspective view of a multi-chip device 1100 having chips S1 and S2 in a stair-step arrangement in some embodiments according to the invention. It will be understood that the chips in the stair-step arrangement are each the same shape and size and are not square shaped, but rather may be, for example, rectangular where one of the dimensions is greater than the other. According to FIG. 12, two rows of chip pads and vias connected thereto are arranged on opposing edges of each of the chip S1 and S2. For example, according to FIG. 12, the chip S1 has opposing rows of chip pads P11-12 and vias V11-12 located on opposing edges thereof. Further, the chip S2 also has two opposing rows of chip pads P21-22 and vias V21-22 connected thereto. According to FIG. 12 the chip pads and vias of each of the chips S1 and S2 are rotated 90 degrees in the direction R relative to the other. For example, as shown in FIG. 12, the chip pads P11-12 and vias V11-12 located on opposing sides of the chip S1 are rotated relative to the chip pads P21-22 and vias V21-22 located on opposing sides of the chip S2.

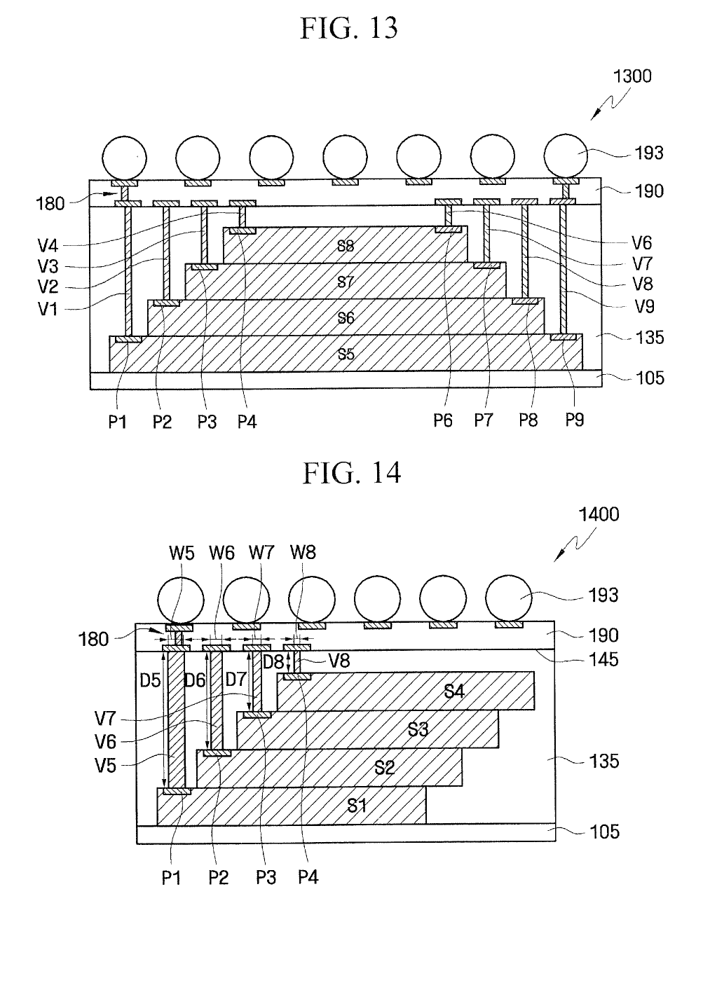

FIG. 13 is a cross-sectional view illustrating a multi-chip device 1300 wherein chips S5-S8 are different shape and size and chip pads P1-P4 and P6-P9 are in an opposing stair-step arrangement that defines a mesa shape profile for the stair-step arrangement of chips S5-S8. Further, each of the vias V1-V4 is connected to the respective chip pad P1-P4 and the vias V6-V9 are connected to respective chip pads P6-P9. All of the vias contact the signal line 180 and ultimately may be provided to the plurality of solder balls 193 for connection to a device on which the multi-chip device 1300 can be mounted.

FIG. 14 is a cross-sectional view of a multi-chip device 1400 having a stair-step arrangement of chips S1-S4 each with a respective chip pad P1-P4 which is connected to a respective via V5-V8. According to FIG. 14, each of the vias extends from the outer surface 145 of the mold packaging material 135 to the respective chip pad P1-P4 and has a respective width W5-W8 at the outer surface 145 that increases with the depth D5-D8 to which the via V5-V8 extends. For example, according to FIG. 14, the width W5 is wider than each of the other width W6-W8 and depth D5 is deeper than each of the other depth D6-D8. Similarly, via V6 is wider than the other vias V7 and V8 which extend to a shallower depth within the mold packaging material 135.

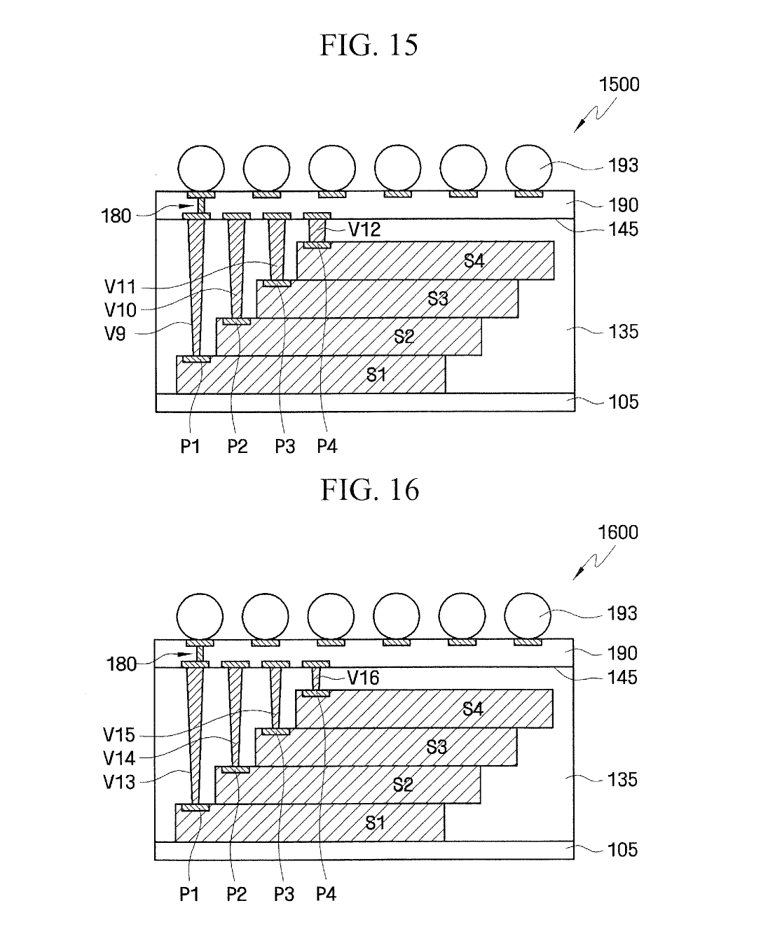

FIG. 15 is a cross-sectional view which illustrates a multi-chip device 1500 having a stair-step arrangement of chips S1-S4 having respective chip pads P1-P4 located thereon in some embodiments according to the invention. Each of the chip pads P1-P4 is contacted by a respective via V9-V12 which extends from the surface of the mold packaging material 135. Still further, the side walls of each of the vias V9-V12 is tapered inward as the via extends down into the mold packaging material 135 to contact the respective chip pad P1-P4. Still further, cross-sectional sizes of each of the vias V9-V12 are substantially equal to one another at the outer surface 145 of the mold packaging material 135, but are unequal at the point at which the respective via V9-V12 contacts the chip pad P1-P4. For example, although the via V9 has an cross-sectional size at the outer surface 145 of the mold packaging material 135 which is substantially equal to the cross-sectional size of via V10, the cross-sectional size of the via V9 at the chip pad P1 is less than the cross-sectional size of the via V10 at the chip pad P2. Accordingly, the cross-sectional size of the via at the chip pad varies inversely with the depth to which the via V9-V12 extends into the mold packaging material 135 from the surface thereof in some embodiments according to the invention. As shown in FIG. 15, the width W9-W12 at the outer surface 145 of the mold packaging material 135 are substantially same.

FIG. 16 is a cross-sectional view which illustrates a multi-chip package 1600 having a plurality of chips S1-S4 and a respective plurality of chip pads P1-P4 located therein in a stair-step arrangement in some embodiments according to the invention. According to FIG. 16, the side walls of the vias V13-V16 which extend from the surface of the mold packaging material 135 to the respective chip pad P1-P4 are tapered inward. The cross-sectional sizes of each of the vias V13-V16 are unequal to one another at the surface of the mold packaging material 135, but are substantially equal at the point at which the respective via V13-V16 contacts the chip pad P1-P4. The cross-sectional size of each of the vias at a point at which it contacts the respective chip pad P1-P4 is substantially independent of the depth to which the via V13-V16 extends into the mold packaging material 135 from the surface thereof in some embodiments according to the invention.

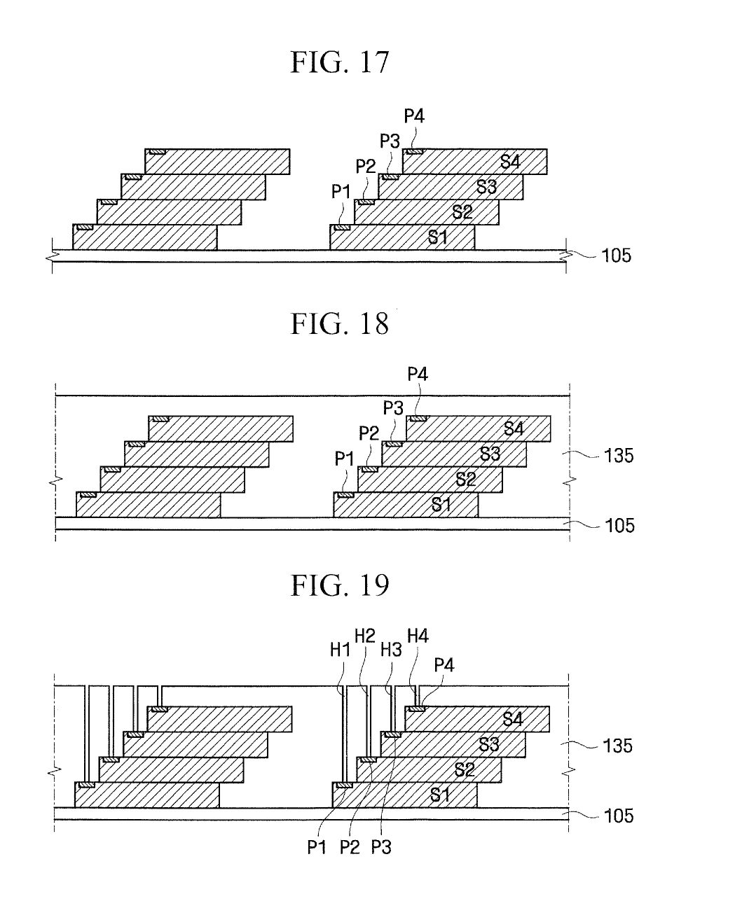

FIGS. 17-21 are cross-sectional views illustrating the formation of multi-chip devices in some embodiments according to the invention. According to FIG. 17, a plurality of chips S1-S4 having respective chip pads P1-P4 thereon are formed in a stair-step arrangement so that the edges of the chips S1-S4 are offset from one another to sufficiently expose the chip pads P1-P4 so that vias may be formed to contact the respective chip pads P1-P4. According to FIG. 18, a mold packaging material 135 is formed over the chips S1-S4 and via holes H1-H4 are formed in the mold packaging material 135 to expose at least a portion of the chip pads P1-P4 as shown in FIG. 19, and to further encapsulate the chips S1-S4 and to cover the upper surface of the upper most chip S4.

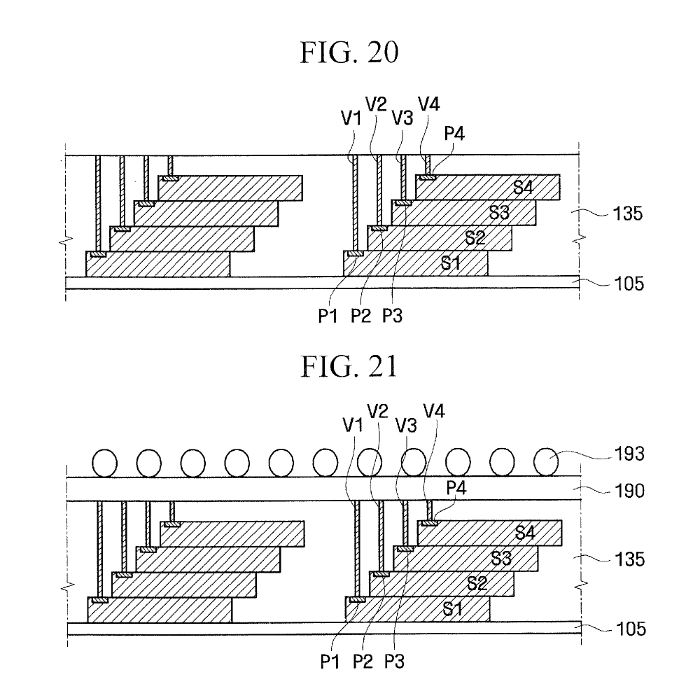

According to FIG. 20, conductive material is formed in the holes H1-H4 to form vias V1-V4 which contact chip pads P1-P4 respectively. According to FIG. 21, the signal line 180 is formed over the mold packaging material 135 and can electically connected to the vias V1-V4. The signal line 180 can be printed circuit board, interposer for redistributing the signal or conductive line formed on a surface of mold packaging material. Still further, a plurality of solder balls 193 can be formed on the signal line 180 to electrically connected to the vias V1-V4 so that the signals conducted thereon can be provided to, for example, a device on which the multi-chip device can be mounted. Still further, the multiple devices formed according to the FIGS. 17-21 can be singulated to form separate multi-chip devices which can be mounted to one another or separately to another underlying structure. The multi-chip packages formed according to the method can be combined with any other type of packages.

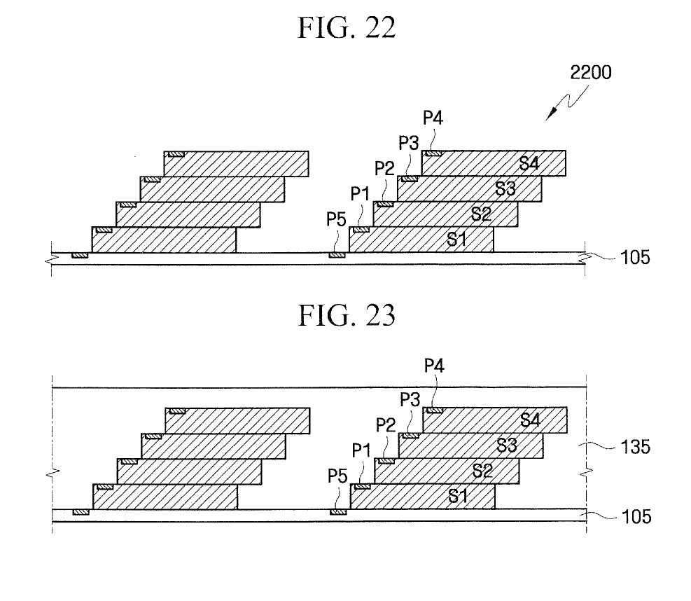

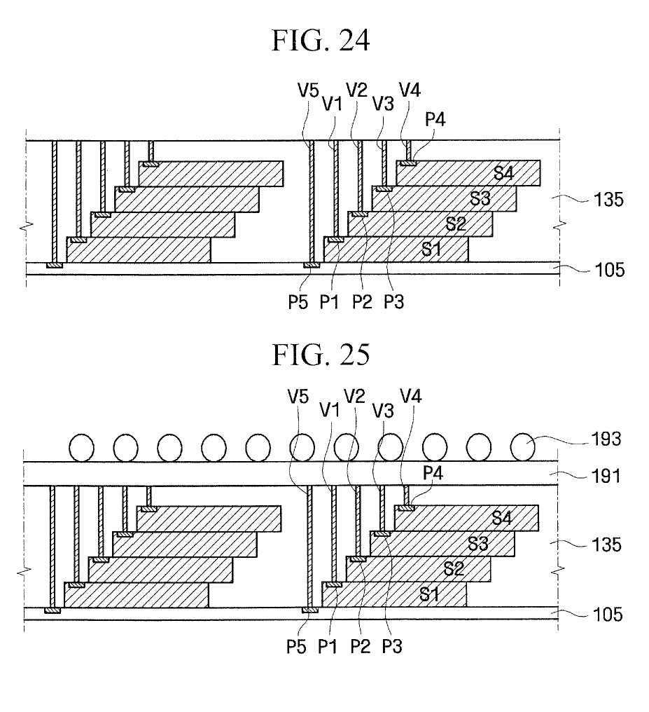

FIGS. 22-26 are cross-sectional views that illustrate methods of forming multi-chip devices in some embodiments according to the invention. According to FIG. 22, a plurality of chips S1-S4 are formed on the supporting layer 105 in a stair-step arrangement so that the edges of the chips S1-S4 are offset from one another so that chip pads P1-P4 formed thereon can be sufficiently exposed to allow contact by vias. According to FIG. 23, a mold packaging material 135 is formed over the plurality chips S1-S4 and to further encapsulate the chips S1-S4 to cover the upper surface of the upper most chip S4. A plurality of vias V1-V5 are formed to extend from a surface of the mold packaging material 135 to contact the respective pads P1-P5 as shown in FIG. 24. It will be understood that as shown in FIGS. 22-24 the supporting layer 105 can have the equivalent of chip pads that can allow the formation of vias thereon so that signals can be provided to/from the protective layer 105 without passing through the stair-step arrangement of chips.

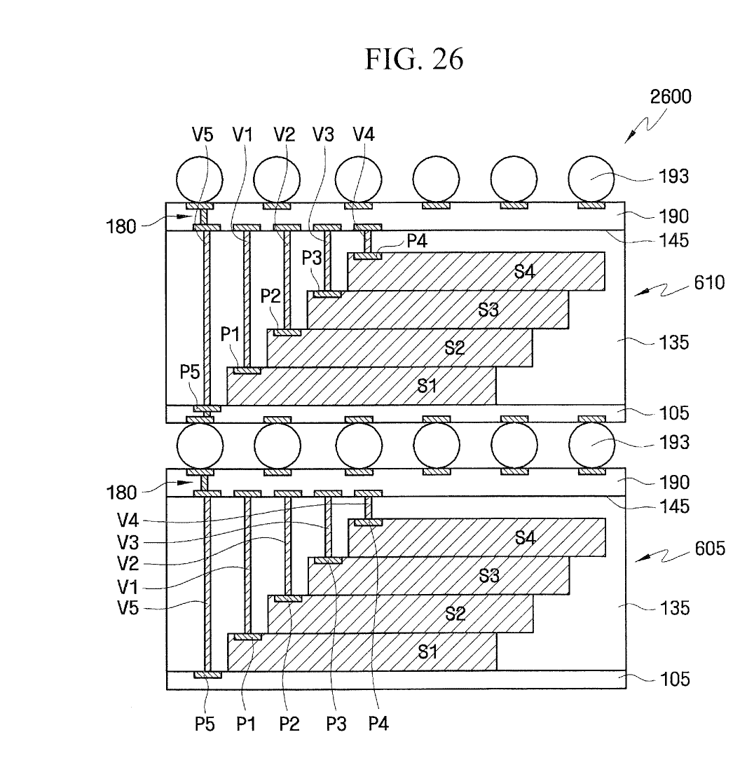

According to FIG. 25, a conductive material is formed in the vias V1-V5 and a signal line 180 is formed thereon to have conductors which can selectively contact ones of the vias V1-V5 which may selectively be provided to solder balls 193 formed on the signal line 180. As further shown in FIG. 25, the via V5 having the conductive material can be used to provide a signal from the protective layer 105 directly to the signal line 180 without passing through the stair-step arrangement of chips S1-S4. According to FIG. 26, different ones of the multi-chip devices formed in FIGS. 22-25 can be singulated and coupled together to form a stacked arrangement.

As described herein, embodiments according to the invention can provide multi-chip packages having a plurality of chips in a stair-step arrangement so that edges of the chips are offset from one another. The offset allows the pads (on the chips) to be sufficiently exposed to allow respective vias (filled with conductive material) to contact the pads. The vias extend through a mold packaging material to contact pads and, for example, a signal redistribution layer which can in turn be coupled to a plurality of solder balls located on the multi-chip package. It will be understood that the vias that extend through the mold packaging material may replace conventional wires so that the height and width of the multi-chip package can be reduced. In other words, use of the vias extending through the mold packaging material from the chip pads to the signal redistribution layer can reduce the spacing allowance that would otherwise be needed to provide space for wires to provide the same interconnect.

It will be apparent to those skilled in the art that various modifications and variations can be made in the invention. Thus, it is intended that the invention covers the modifications and variations of this invention provided they come within the scope of the appended claims and their equivalents.

What is claimed:

1. A multi-chip device comprising:
a signal line having via contacts;
a plurality of chips in a stair-step arrangement formed on the signal line and having respective chip pads thereon;
a mold packaging material encapsulating the plurality of chips; and
at least one conductive via formed through the mold packaging material and electrically connecting one of the chip pads to one of the via contacts.

2. A multi-chip device according to claim 1, wherein the at least one conductive via further comprises a plurality of conductive vias in the mold packaging material having different length from the chip pads to the via contacts.

3. A multi-chip device according to claim 1, wherein the at least one conductive via further comprises a plurality of conductive vias in the mold packaging material each extending from an outer surface of the mold packaging material to chip pads located on opposing sides of the chips in the opposing stair-step arrangements.

4. A multi-chip device according to claim 1, wherein the stair-step arrangement comprises that edges of the plurality of chips are offset from one another to expose the chip pads sufficiently to allow contact by the conductive vias.

5. A multi-chip device according to claim 4, wherein the pads are located along a single one of the edges of the plurality of chips and the edges of the plurality of chips are offset in a single direction.

6. A multi-chip device according to claim 4, wherein the pads are located along two adjacent ones of the edges of the plurality of chips and the edges of the plurality of chips are offset in at least two directions.

7. A multi-chip device according to claim 1, wherein the plurality of chips comprise substantially equal sizes and the stair-step arrangement comprises an inverted stair-step arrangement or a non-inverted stair-step arrangement relative to a signal redistribution layer on the mold packaging material.

8. A multi-chip device according to claim 1, wherein the mold packaging material comprises an epoxy molding compound.

9. A multi-chip device according to claim 1, further comprising:
a substrate on the mold packaging material having at least one via contact on the first surface of the substrate and at least one solder ball land on the second surface of the substrate opposite the first surface; and
at least one solder ball on the solder ball land of the substrate.

10. A multi-chip device according to claim 1, wherein the at least one conductive via further comprise a plurality of conductive vias in the mold packaging material and the plurality of conductive vias have at least two different length from the chip pads to via contacts.

11. A multi-chip device according to claim 1, wherein the at least one conductive via further comprises a plurality of conductive vias in the mold packaging material each extending from the outer surface of the mold packaging material to contact respective chip pads, wherein respective widths of the plurality of conductive vias increase with respective depths of the vias.

12. A multi-chip device according to claim 1, wherein the at least one conductive via further comprises a plurality of conductive vias in the mold packaging material each extending from the outer surface of the mold packaging material to contact respective chip pads, wherein respective sidewalls of the plurality of conductive vias are tapered inwardly and the plurality of conductive vias have substantially equal sized cross-sections at the outer surface.

13. A multi-chip device according to claim 1, wherein the at least one conductive via further comprises a plurality of conductive vias in the mold packaging material each extending from the outer surface of the mold packaging material to contact respective chip pads, wherein respective sidewalls of the plurality of conductive vias are tapered inwardly and the plurality of conductive vias have substantially equal sized cross-sections at bottoms of the vias.

14. A multi-chip device according to claim 1, wherein the at least one conductive via extends from the outer surface of the mold packaging material to contact a chip pad on one of the plurality of chips, the device further comprising:
a plurality of wires bonded to the chip pad which contacted to the conductive via and respective contact pads located on remaining ones of the plurality of chips.

15. A multi-chip device according to claim 1, wherein the at least one conductive via extends from the outer surface of the mold packaging material to contact a chip pad on one of the plurality of chips, the device further comprising:
a plurality of wires daisy-chain bonded to respective contact pads located on remaining ones of the plurality of chips.

16. A multi-chip device according to claim 1, wherein the plurality of chips comprise substantially equal sizes including respective chip pads located along a single respective edge of the each of the chips, wherein each of the single respective edges is rotated by 90 degrees relative to immediately adjacent upper and lower ones of the plurality of chips.

17. A multi-chip device according to claim 1, wherein the plurality of chips comprise substantially equal rectangular sizes including respective chip pads located along two opposing respective edges of the each of the chips, wherein each of the chips is rotated by 90 degrees relative to immediately adjacent upper and lower ones of the plurality of chips.

18. A multi-chip device according to claim 1, wherein the multi-chip device comprising a first device, the multi-chip device further including a second device on the first device comprising:
a plurality of second chips in an inverted stair-step arrangement including respective second chip pads thereon facing the chip pads on the plurality of chips in the first device;
a second mold packaging material encapsulating the plurality of second chips;
a common signal line located between the first and second devices; and
at least one second conductive via in the second mold packaging material extending from common signal redistribution layer to contact a respective one of the second chip pads.

19. A multi-chip device according to claim 18, wherein the first and second plurality of chips are arranged so that respective active areas of the chips face one another and the pads of the first and second plurality of chips are offset relative to one another.

20. A multi-chip device comprising:
a plurality of first solder balls;
a first signal line electrically connected to the plurality of first solder balls;
a plurality of first chips in a first stair-step arrangement having respective chip pads thereon;
a first mold packaging material encapsulates at least a portion of the plurality of first chips;
a plurality of first conductive vias, in the first mold packaging material extending from a surface adjacent the first signal line to respective chip pads;
a second signal line on the first mold packaging material opposite the first signal redistribution layer;
a plurality of second solder balls on the second signal line wherein one of the second solder balls is electrically connected to the second signal line;
a third signal line electrically connected to the plurality of second solder balls;
a plurality of second chips in a second stair-step arrangement having respective chip pads thereon;
a second mold packaging material encapsulates at least a portion of the plurality of second chips; and
at least one second conductive via in the second mold packaging material extending from the third signal line to a respective one of the chip pads.
